(19) United States
(12) Patent Application Publication
(10) Pub. No.: US 2023/0064070 A1
(43) Pub. Date: Mar. 2, 2023

(54) SEMICONDUCTOR PROCESSING EQUIPMENT PART AND METHOD FOR MAKING THE SAME

(71) Applicant: AUO Crystal Corporation, Taichung City (TW)

(72) Inventor: Chang-Ho YU, Taichung City (TW)

(21) Appl. No.: 17/562,502

(22) Filed: Dec. 27, 2021

Related U.S. Application Data
(60) Provisional application No. 63/238,400, filed on Aug. 30, 2021.

(51) Int. Cl. H01J 37/32; C23C 14/00

(52) U.S. Cl. CPC H01J 37/32642; C23C 14/0021; H01J 2237/3341

(57) ABSTRACT

A part is adapted to be used in a semiconductor processing equipment. The part includes a substrate and a protective coating. The protective coating covers at least a part of the substrate, is made of silicon carbide, and has an atomic ratio of carbon in the protective coating increases in a direction away from the substrate while an atomic ratio of silicon in the protective coating decreases in the direction. The atomic ratio of silicon in the protective coating is larger than that of the carbon near the substrate, and the atomic ratio of silicon in the protective coating is smaller than that of carbon near the outer surface of the protective coating. A method for making the part is also provided.

### CROSS-REFERENCE TO RELATED APPLICATION

This application claims priority of U.S. Provisional Patent Application No. 63/238,400, filed on Aug. 30, 2021.

### FIELD

The disclosure relates to an equipment part, more particularly to a part of a semiconductor processing equipment and a method for making the part.

### BACKGROUND

In the field of semiconductor technology, various pieces of semiconductor processing equipment are required for making semiconductor chips. Those pieces of equipment may include, but not limited to, thin film deposition equipment, etching equipment, photolithography equipment, etc. Such equipment include various parts or components, e.g., focus rings, edge rings, chamber walls, etc. that requires protection in order to withstand long-term use of the processing equipment. Protective layers are often formed on substrates of the parts to provide protection to the parts. For example, new protecting layers may be formed on the substrates of the parts once the old protective layers are damaged during semiconductor manufacturing processes, allowing the parts to be reused. However, the protecting layers might be easily peeled off from the parts due to various factors, such as interlayer stress, lattice mismatch, etc. Therefore, it is desirable in the art to provide a part with a protecting layer that has superior adhesion to the substrate and that is durable enough to withstand regular use.

### SUMMARY

According to one aspect of the disclosure, a part is adapted to be used in a semiconductor processing equipment. The part includes a substrate made of silicon, and a protective coating that covers at least a part of the substrate. An atomic ratio of carbon in the protective coating increases in a direction away from the substrate, and an atomic ratio of silicon in the protective coating decreases in the direction. The atomic ratio of silicon in the protective coating is larger than that of carbon near the substrate and the atomic ratio of silicon in the protective coating is smaller than that of carbon near the outer surface of the protective coating.

According to another aspect of the disclosure, a method for making a part adapted to be used in a semiconductor processing equipment is provided. The method includes: introducing an inert gas into a chamber which contains a plurality of silicon targets and a substrate made of silicon; introducing a reactive gas which includes an element of carbon into the chamber; and ionizing the inert gas into plasma such that the plasma hits the silicon targets, causing silicon atoms to break away from the silicon targets and to react with the reactive gas to form a protective coating made of silicon carbide that covers at least a part of the substrate.

### BRIEF DESCRIPTION OF THE DRAWINGS

Other features and advantages of the disclosure will become apparent in the following detailed description of the embodiment with reference to the accompanying drawings, of which:

FIG. 1 is, in accordance with some embodiments, a flow chart of a method for making a part adapted to be used in a semiconductor processing equipment;

FIG. 2 is, in accordance with some embodiments, a schematic view of a reactive physical vapor deposition equipment for performing the method;

FIG. 3 is a schematic top view of a substrate of the part in accordance with some embodiments;

FIG. 4 is a schematic sectional view taken from line IV-IV of FIG. 3;

FIG. 5 is a schematic view showing a protective coating being formed on the substrate;

FIGS. 6 to 11 are schematic views showing different variations of the protective coating;

FIGS. 12 and 13 shows different arrangements of silicon targets of the reactive physical vapor deposition equipment;

FIG. 14 is an enlarged schematic view showing a plurality of microstructures of the substrate;

FIG. 15 is enlarged schematic view showing a variation of the microstructures having pyramid shape of the substrate;

FIG. 16 is a scanning electron microscope (SEM) image of an example of the part;

FIG. 17 shows a result of energy-dispersive X-ray spectroscopy (EDS) analysis of the protective coating of the example shown in FIG. 16;

FIG. 18 shows a result of X-ray diffraction (XRD) analysis of the protective coating of the example shown in FIG. 16;

FIG. 19 is an SEM image of another example of the part;

FIG. 20 shows a result of EDS analysis of the protective coating of the example shown in FIG. 19;

FIG. 21 shows a result of XRD analysis of the protective coating of the example shown in FIG. 19;

FIG. 22 is an SEM image of yet another example of the part;

FIG. 23 shows a result of EDS analysis of the protective coating of the example shown in FIG. 22;

FIG. 24 shows a result of XRD analysis of the protective coating of the example shown in FIG. 22;

FIGS. 25 to 28 are SEM images of the substrate and the examples shown in FIGS. 16, 19 and 22 which were etched after a reactive ion etching (RIE) process; and

FIGS. 29 to 34 show high resolution transmission electron microscope images and diffraction patterns of the samples of FIGS. 16, 19 and 22.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

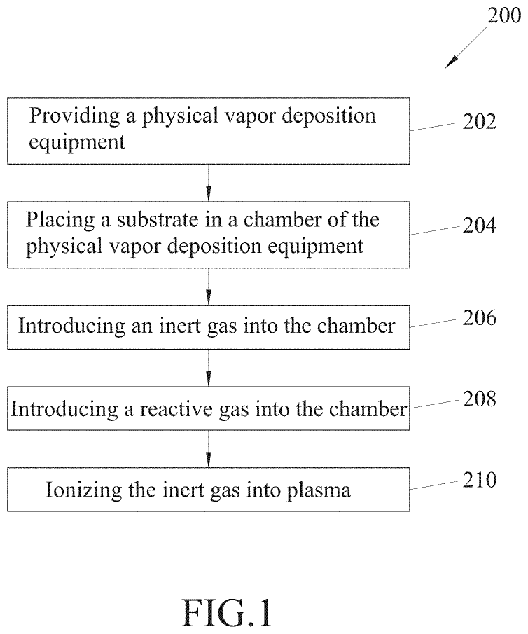

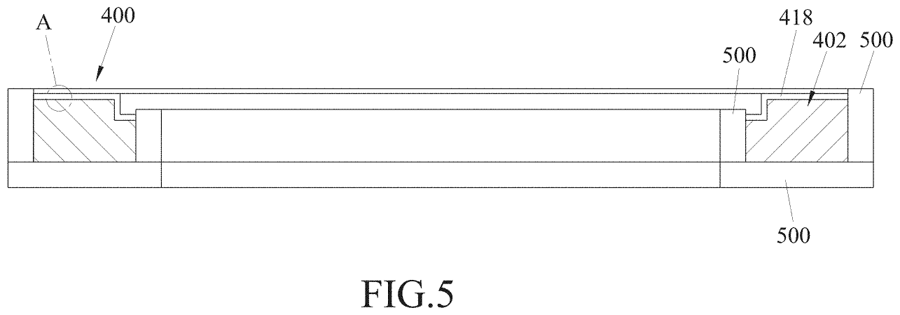

FIG. 1 is a flow chart 200 of a method for making a part 400 (see FIG. 5) adapted to be used in a semiconductor processing equipment. In some embodiments, the part 400 may be a component of the semiconductor processing equipment, such as devices for performing etching (e.g., dry etching or other etching techniques), thin film deposition (e.g., atomic layer deposition, physical vapor deposition, chemical vapor deposition, plasma enhanced chemical vapor deposition etc.), or other semiconductor manufacturing processes. For example, the part 400 may be a focus ring, an edge ring, a shadow ring, an electrode plate, a shower head, an interior wall of a process chamber, a chuck, a susceptor or pedestal of thin film deposition equipment, a wafer boat, or other suitable equipment parts. The disclosure may also be applied to a coated wafer with SiC coating on a substrate (e.g., silicon substrate) using the same method. In some embodiments, the SiC coating can be regarded as a functional layer with a thickness ranging from several angstroms to a few millimeters. For example, the functional layer may has functions such as low thermal expansion, high thermal conductivity, excellent thermal shock resistance, oxidation resistance, serving as a buffer layer, etc. In some embodiments, at least a different layer, such a GaN layer, may be further deposited on the SiC functional layer.

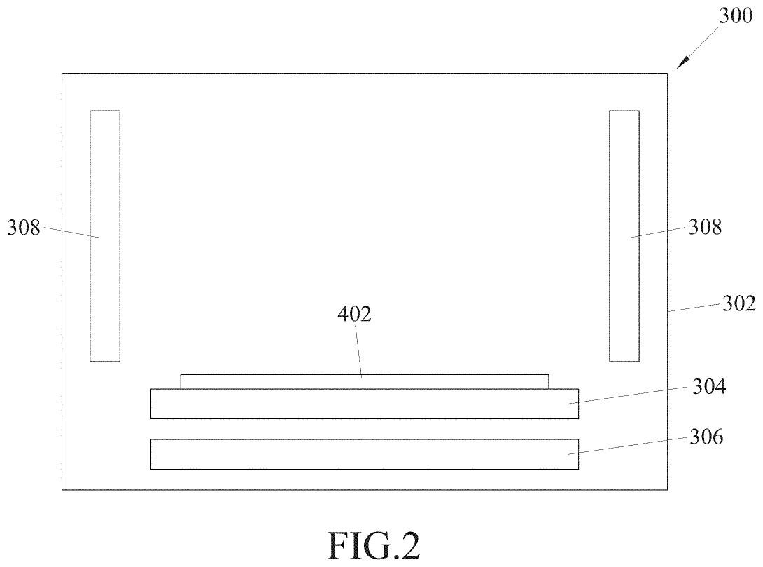

Referring to FIGS. 1 and 2, in step 202, a reactive physical vapor deposition equipment 300 is provided. In some embodiments, the reactive physical vapor deposition equipment 300 includes a chamber 302, a holder 304 that is disposed in the chamber 302, and a plurality of silicon targets 308 that are placed in the chamber 302. In some embodiments, the silicon targets 308, in even numbers, may be disposed parallel to each other above and perpendicular to the holder 304. In some embodiments, the reactive physical vapor deposition equipment 300 further includes a heater 306 that is used for heating the holder 304. The heater 306 may be a graphite heater, an IR laser heater or other suitable heating devices. The heater 306 may be disposed in the chamber 302 or outside of the chamber 302, as long as the holder 304 can be effectively heated.

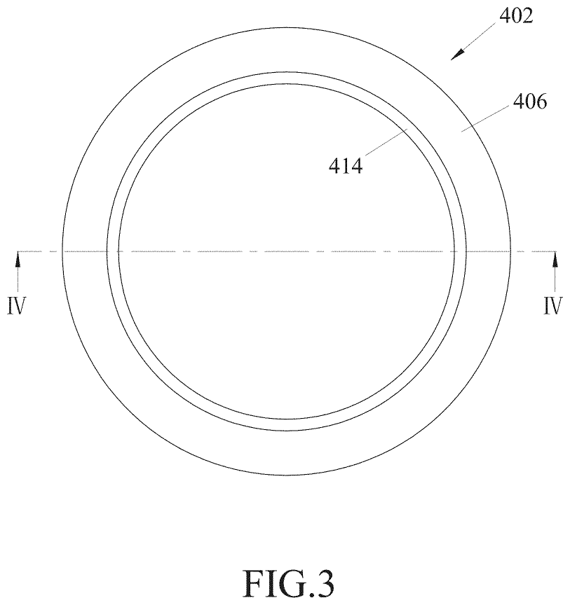

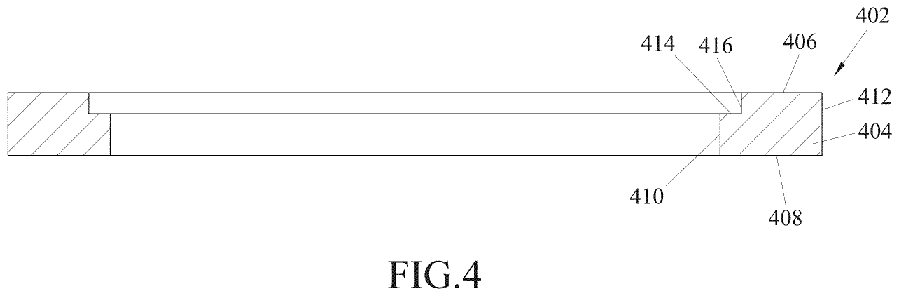

Referring to FIGS. 1 and 2, in step 204, a substrate 402 is placed in the chamber 302 on the holder 304. In some embodiments, the substrate 402 may be made of one of silicon, silicon carbide, silicon oxide and graphite, or other suitable materials. Referring to FIG. 3, in some embodiments, the substrate 402 is a closed-loop object, and is exemplified to be ring-shaped, but other suitable shapes are also possible, according to practical requirements. A cross-section of the substrate 402 along line IV-IV of FIG. 3 is shown in FIG. 4. In some embodiments, the substrate 402 has a main body 404 that has opposite inner and outer surfaces 410, 412, opposite upper and lower surfaces 406, 408, and a horizontal surface 414 and vertical surface 416 that cooperates with the horizontal surface 414 to define a step. In some embodiments, the horizontal surface 414 may be substantially perpendicular to the inner surface 410; but in other embodiments, the horizontal surface 414 may be inclined relative to the inner surface 410. In some embodiments, the vertical surface 416 may be substantially perpendicular to the upper surface 406; but in other embodiments, the vertical surface 416 may be inclined relative to the upper surface 406.

Referring to FIGS. 1 and 2, in step 206, an inert gas is introduced into the chamber 302 through a gas inlet (not shown) of the chamber 302. In some embodiments, the inert gas may be Ar, He, Ne, Kr, or any combination thereof. In some embodiments, the flow rate of the inert gas may range from 5 slm to 24 slm, but other ranges are also possible based on practical requirements.

Referring to FIGS. 1 and 2, in step 208, a reactive gas is introduced into the chamber 302 through another gas inlet (not shown) of the chamber 302. In some embodiments, the reactive gas includes an element of carbon (e.g., C₂H₂, CH₄, etc.). In some embodiments, the reactive gas may be a hydrocarbon gas having a formula of CₙH₍₂ₙ₋₂₎, CₙHₙ, CₙH₍₂ᵣₙ₊₂₎, or other suitable formulas, where n is a positive integer. In some embodiments, the flow rate of the reactive gas may range from 10 sccm to 120 sccm, but other ranges are also possible based on practical requirements.

Referring to FIGS. 1 and 2, in step 210, the inert gas is ionized into plasma including ions that hit the silicon targets 308, causing silicon atoms and/or silicon ions to break away from the silicon targets 308 and to react with the reactive gas so as to form a protective coating 418 made of silicon carbide that covers at least a part of the substrate 402, thereby obtaining the part 400 which includes the substrate 402 and the protective coating 418 covering at least a part of the substrate 402. The protective coating 418, for example, can protect the substrate 402 of the part 400 from being damaged by dry etch gas (e.g., Cl₂, F₂, O₂, CF₄, C₃F₈, CHF₃, XeF₂, SF₆, HBr, chloride gases, etc.) when the part 400 is used in an etching equipment. In some embodiments, a radiofrequency power for ionizing the inert gas ranges from 0.4 kW to 1.2 kW, but other ranges are also possible based on practical requirements. In some embodiments, the protective coating 418 is formed at a rate of not less than 6 Å/sec. In some embodiments, the protective coating 418 may have a minimum thickness not less than 1.5 μm. Referring further to FIG. 5, in some embodiments, a plurality of covering units 500 may be attached to the substrate 402 during the formation of the protective coating 418, such that only a desired part of the substrate 402 is exposed and formed with the protective coating 418. For example, as shown in FIGS. 4 and 5, the lower surface 408, the inner surface 410 and the outer surface 412 of the main body 404 of the substrate 402 may be covered by the covering units 500 such that only the upper surface 406, the horizontal surface 414 and the vertical surface 416 of the substrate 402 are covered with the protective coating 418. After forming the protective coating 418, the covering units 500 are removed from the substrate 402. In some embodiments, the covering units 500 may be jigs, masks, tapes, any combination thereof, or other suitable materials.

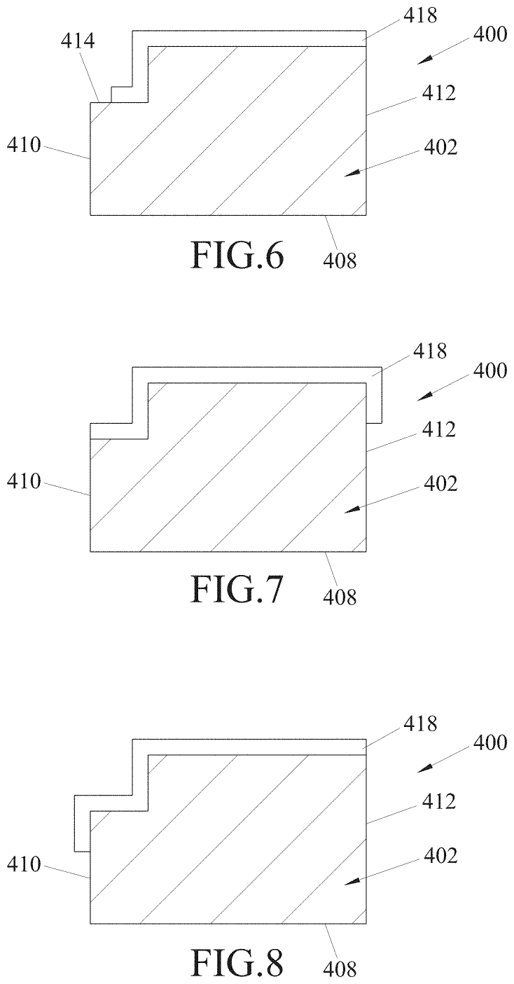

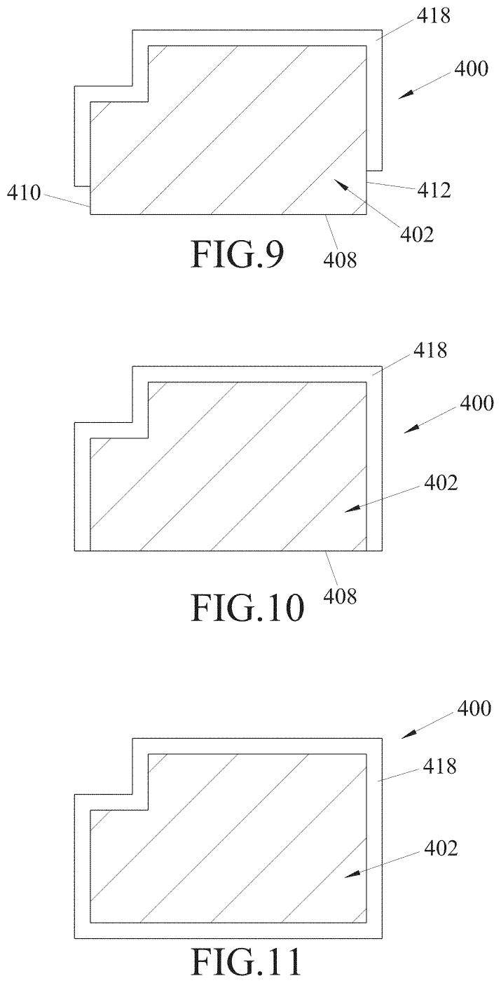

FIGS. 6 to 11 schematically show different variations of the protective coating 418. Referring to FIGS. 4 and 6, the protective coating 418 may cover the upper surface 406, the vertical surface 416 and a part of the horizontal surface 414 of the substrate 402. Referring to FIGS. 4 and 7, the protective coating 418 may cover the upper surface 406, the vertical surface 416, the horizontal surface 414 and a part of the outer surface 412 of the substrate 402. Referring to FIGS. 4 and 8, the protective coating 418 may cover the upper surface 406, the vertical surface 416, the horizontal surface 414, and a part of the inner surface 410 of the substrate 402. Referring to FIGS. 4 and 9, the protective coating 418 may cover the upper surface 406, the vertical surface 416, the horizontal surface 414, a part of the inner surface 410 and a part of the outer surface 412 of the substrate 402. Referring to FIGS. 4 and 10, the protective coating 418 may cover the upper surface 406, the vertical surface 416, the horizontal surface 414, the inner surface 410 and the outer surface 412 of the substrate 402. Referring to FIGS. 4 and 11, the protective coating 418 may entirely cover the main body 404 of the substrate 402, including the upper surface 406, the lower surface 408, the inner surface 410, the outer surface 412, the horizontal surface 414, and the vertical surface 416. In addition, each of the examples shown in FIGS. 4 to 10 may be selectively added with an anti-warpage layer (not shown) on the lower surface 408 in case the stress of the protective coating 418 causes the substrate 402 to bend. The material of the anti-warpage layer may also be selected as silicon carbide but is not limited to silicon carbide as long as it can compensate the warpage of the substrate 402.

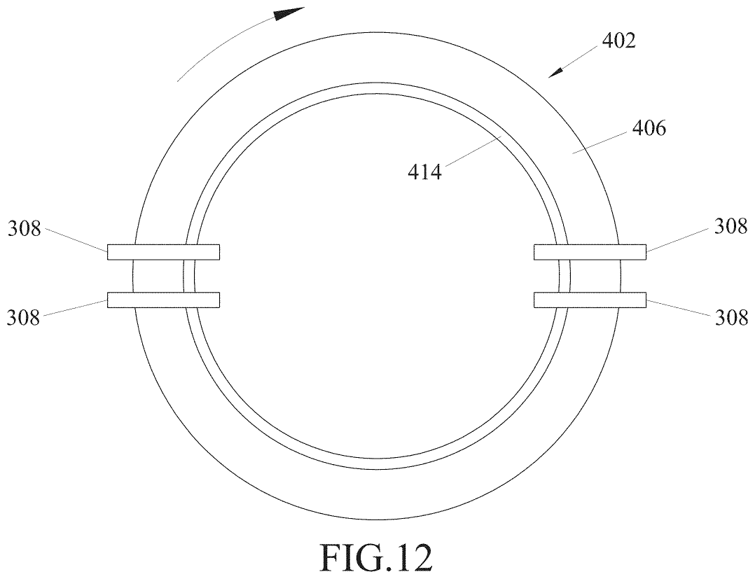

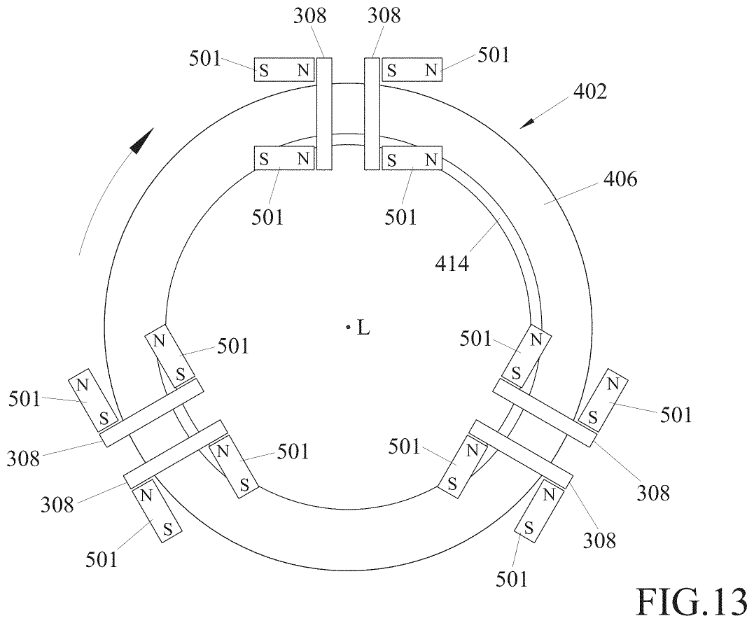

Referring to FIG. 2, in some embodiments, an even number of the silicon targets 308 are placed in the chamber 302. In some embodiments, the silicon targets 308 are arranged in at least one pair with the silicon targets 308 facing each other. Specifically, if the number of the silicon targets 308 is two, the silicon targets 308 may be mounted to the chamber 302 to be located opposite to each other, or may be placed closer to each other (see FIG. 12) with a short distance such as several millimeters to hundreds of millimeters. With the number of the silicon targets 308 being even, the plasma and/or the gas atoms/ions would be more likely to hit the silicon targets 308, which may result in formation of a denser silicon carbide protective coating 418. If the number of the silicon targets 308 is greater than two, such as four, six, eight, etc., the silicon targets 308 may be arranged as multiple pairs. For example, as shown in FIG. 13, there are three pairs of silicon targets 308 disposed above the substrate 402 by equiangular arrangement. In some embodiments, the substrate 402 such as a closed-loop object or ring rotates about a virtual center axis (L) during formation of the protective coating 418 in order to adjust or improve the uniformity of the protective coating 418. In some embodiments, two sides of each pair of the silicon targets 308 are provided with magnets 501 to produce magnetic field to control the plasma located within the magnetic field in order to improve efficiency of forming the silicon atoms/ions or adjust plasma erosion uniformity of the pair of the silicon targets 308.

Referring to FIG. 2, in some embodiments, the substrate 402 may be biased to have a lower voltage relative to the plasma. For example, when the plasma is positively charged (e.g., plasma containing Ar⁺), the substrate 402 is negatively changed, thereby attracting some ions of the plasma to hit the substrate 402. The attracted ions of plasma may clean the surfaces of the substrate 402 by removing native oxidized layers formed thereon when the substrate 402 is exposed to air, moisture or other substances. Furthermore, the plasma having gas ions such as Ar⁺ may create dangling bonds on the surfaces of the substrate 402 which may be reactive to the silicon atoms, silicon ions, carbons, and/or silicon carbide. Therefore, the protective coating 418 may be physically and/or chemically connected to the substrate 402 (e.g., the protective coating 418 is connected to the substrate 402 through chemical bonding with the dangling bonds), so that the protective coating 418 may be more firmly attached to the substrate 402.

Referring to FIG. 2, in some embodiments, the substrate 402 may be heated by the heater 306, such that the protective coating 418 may be more firmly attached to the substrate 402 and/or the crystallinity of the protective coating 418 may be increased (i.e., the protective coating 418 being made denser). The heating temperature may be any temperature ranging from room temperature to a temperature lower than the melting points of the substrate 402 and the protective coating 418 (i.e., silicon carbide).

In some embodiments, during the formation of the protective coating 418, the holder 304 may be rotated, horizontally moved, and/or vertically moved to rotate or move the substrate 402 for various purposes, e.g., adjusting the uniformity of the protective coating 418, etc.

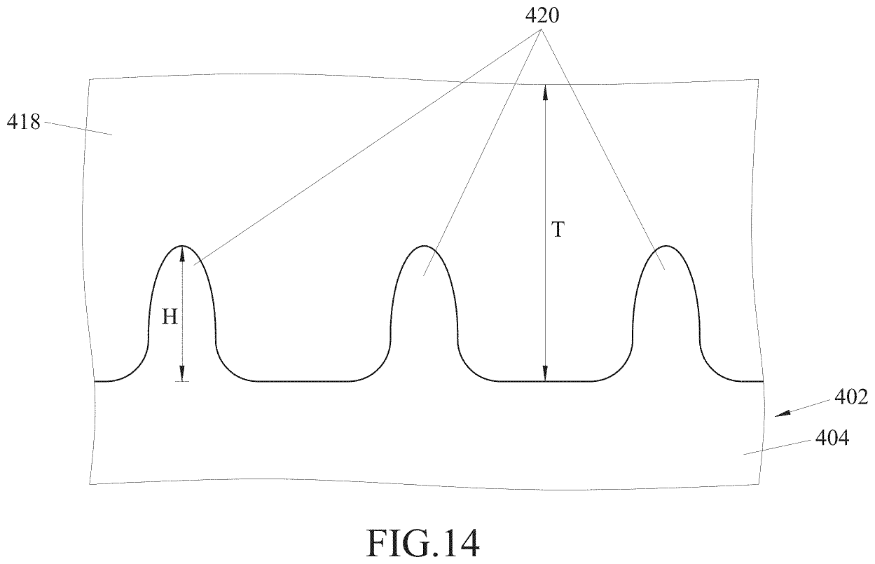

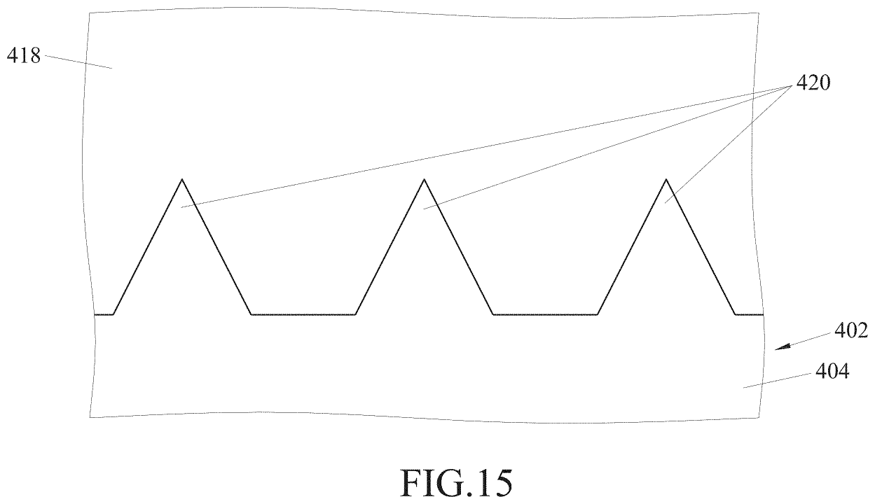

FIG. 14 is a schematic sectional view taken from circle (A) shown in FIG. 5. In some embodiments, the main body 404 of the substrate 402 may be formed with a plurality of microstructures 420 such as protrusions before the formation of the protective coating 418, such that, after the protective coating 418 is formed on the main body 404 of the substrate 402, the stress between the substrate 402 and the protective coating 418 can be reduced and the protective coating 418 can be more firmly attached to the substrate 402. In some embodiments, each of the microstructures 420 may have a height (H) in a range from 300 nm to 1.5 μm and the protective coating 418 thereon has a minimum thickness (T) of not less than 10 μm. Referring to FIG. 15, in some embodiments, each of the microstructures 420 is pyramid-shaped and has a triangular cross-section. The microstructures 420 may be formed by etching the substrate 402 with a suitable etchant, may be formed by deposition techniques, or formed using other suitable techniques. In some embodiments, the substrate 402 made of silicon may be etched by potassium hydroxide (KOH), tetramethyl ammonium hydroxide (TMAH), ethylenediamine pyrocatechol (EDP), etc.

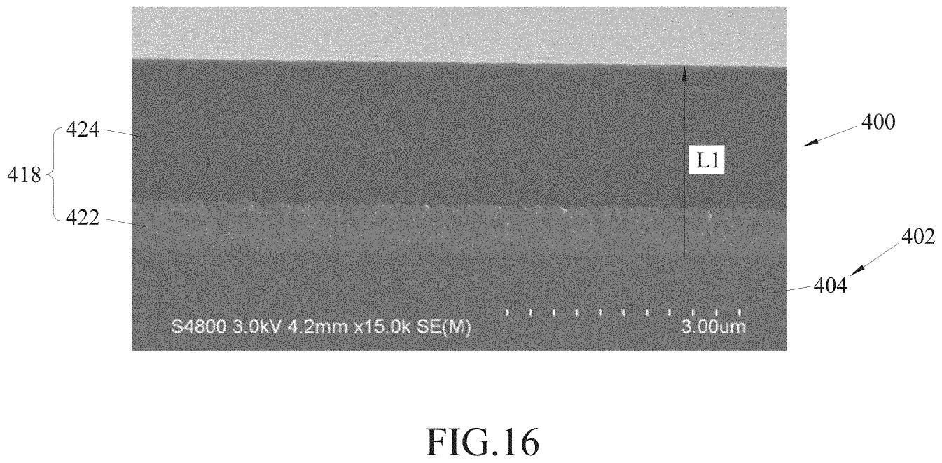

FIG. 16 is a scanning electron microscope (SEM) image of an example of the part 400. In the process for making this example, the inert gas is Ar with a flow rate ranging from 5 slm to 24 slm, but other ranges are also possible based on practical requirements. The reactive gas is C₂H₂ with a flow rate ranging from 10 sccm to 36 sccm, but other ranges are also possible based on practical requirements. The pressure within the chamber 302 ranges from 10⁻¹ torr to 10⁻² torr, but other ranges are also possible based on practical requirements. The radiofrequency power for ionizing the inert gas initially ranges from 0.4 kW to 0.7 kW, but other ranges are also possible based on practical requirements. Then, the radiofrequency power is increased to a range of 0.7 kW to 1.2 kW, but other ranges are also possible based on practical requirements. The temperature of the deposition process may be below 250° C., but other ranges are also possible based on practical requirements. For example, a deposition temperature of 700° C. can increase the ratio of crystalline silicon carbide which enhances the etch resistance capability of the protective coating 418. In other words, in some embodiments of the method for making the part 400, at least one of the flow rate of the inert gas, the flow rate of the reactive gas, and the radiofrequency power for ionizing the inert gas dynamically changes and ends up with a larger numerical value compared to an initial numerical value (i.e., the abovementioned values may be dynamically increased) during the process of formation of the protective coating 418.

As shown in FIG. 16, the protective coating 418 of the part 400 was formed to have a first portion 422 and a second portion 424. The first portion 422 is connected to the substrate 402 and the second portion 424, and has a larger atomic ratio of silicon near the substrate 402 than that of the second portion 424.

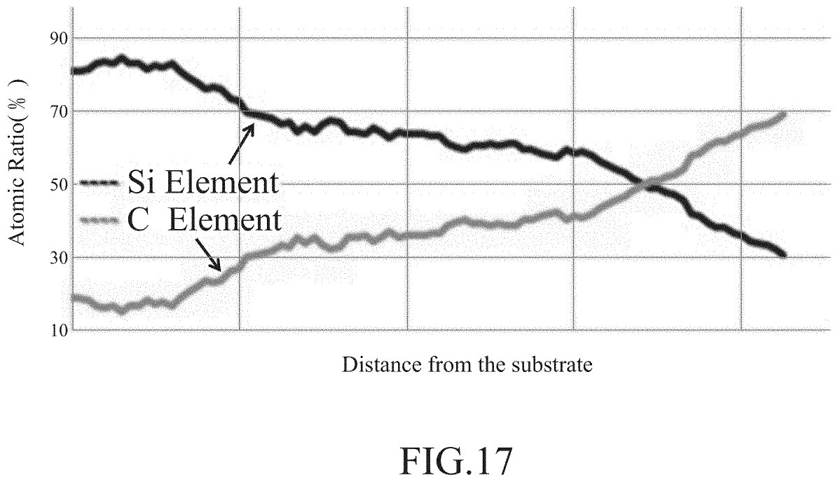

FIG. 17 is a chart showing the result of energy-dispersive X-ray spectroscopy (EDS) analysis taken along line (L1) of FIG. 16. As shown in FIGS. 16 and 17, the carbon content (i.e., the atomic ratio of carbon_) in the protective coating 418 increases along the line (L1) (e.g., increases in a direction away from the substrate 402), and the silicon content (i.e., the atomic ratio of silicon) in the protective coating 418 decreases in the direction away from the substrate 402. In other words, an atomic ratio of silicon is larger than the atomic ratio of carbon near the substrate 402. On the contrary, the atomic ratio of silicon is smaller than the atomic ratio of carbon near the outer surface of the protective coating 418 away from the substrate 402. More specifically, the atomic ratio of silicon is larger than 75% while that of carbon is smaller than 25% near the substrate 402 and the atomic ratio of carbon is about 70% while that of silicon is about 30% near the outer surface of the protective coating 418. The average relative content of silicon to carbon in the protective coating 418 is near 3/2 (i.e., Si:C=60:40). The curve of silicon element and the curve of carbon intersect at a point larger than one half of the distance from the substrate 402. As a result, the silicon content as a whole would be larger than the carbon content as a whole in the protective coating 418. When the substrate 402 is made of silicon, and by having the protective coating 418 with a high silicon content close to the substrate 402, the protective coating 418 may be more firmly attached to the substrate 402.

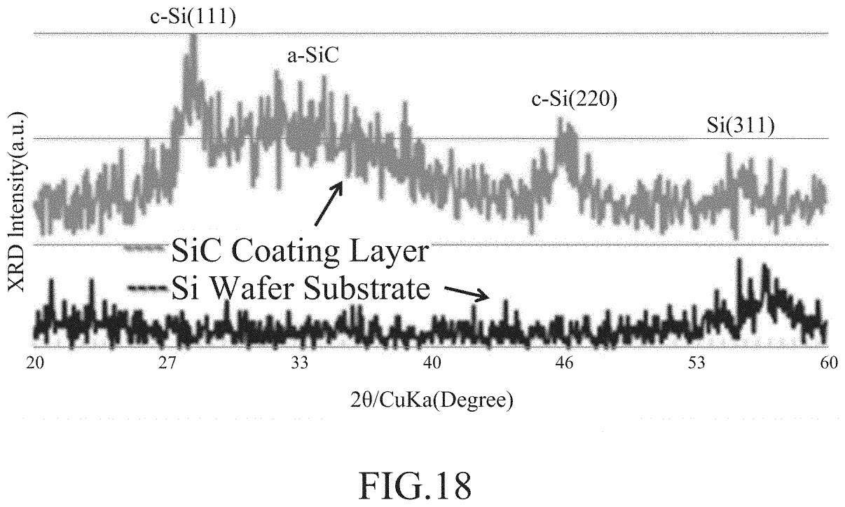

FIG. 18 is the result of X-ray diffraction (XRD) analysis of the surface of the protective coating 418 shown in FIG. 16. The protective coating 418 at least contains c-Si(111), c-Si(220), and 3C—SiC such as amorphous silicon carbide (a-SiC) and a little β-SiC(111) (not shown). That is, the protective coating 418 includes 3C—SiC and crystalline silicon having (111) facets, (220) facets, or a combination thereof.

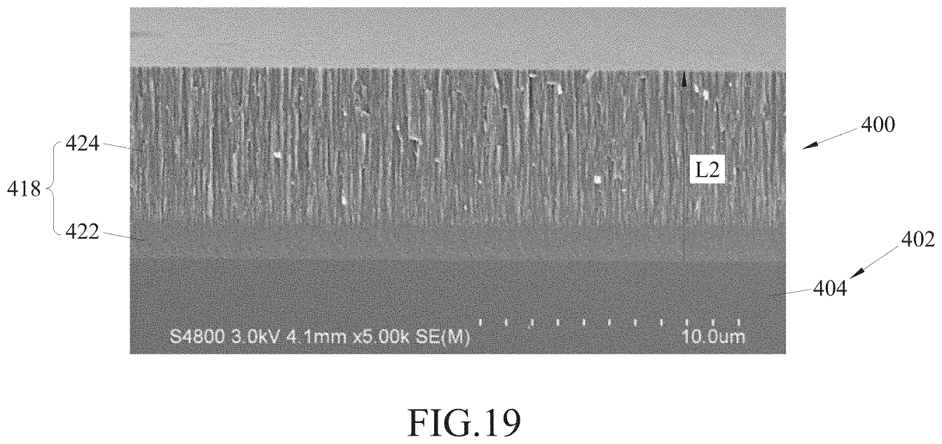

FIG. 19 is an SEM image of another example of the part 400. In the process for making this example, the inert gas is Ar with a flow rate ranging from 5 slm to 17 slm, but other ranges are also possible based on practical requirements. The reactive gas is C₂H₂ with a flow rate ranging from 10 sccm to 60 sccm, but other ranges are also possible based on practical requirements. The pressure within the chamber 302 ranges from 10⁻¹ torr to 10⁻² torr, but other ranges are also possible based on practical requirements. The radiofrequency power for ionizing the inert gas initially ranges from 0.4 kW to 0.7 kW, but other ranges are also possible based on practical requirements. Then, the radiofrequency power is increased to a range of 0.7 kW to 1.2 kW, but other ranges are also possible based on practical requirements. The temperature of the deposition process may be below 250° C., but other ranges are also possible based on practical requirements. For example, a deposition temperature of 1000° C. can increase the ratio of crystalline silicon carbide which enhances the etch resistance capability of the protective coating 418. In other words, in some embodiments of the method for making the part 400, at least one of the flow rate of the inert gas, the flow rate of the reactive gas, and the radiofrequency power for ionizing the inert gas dynamically changes and ends up with a larger numerical value compared to an initial numerical value (i.e., the abovementioned values may be dynamically increased) during the process of formation of the protective coating 418.

As shown in FIG. 19, the protective coating 418 of the part 400 was formed to have the first portion 422 and the second portion 424 which has a columnar-like structure. The first portion 422 is connected to the substrate 402 and the second portion 424, and has a larger atomic ratio of silicon near the substrate 402 than that of the second portion 424.

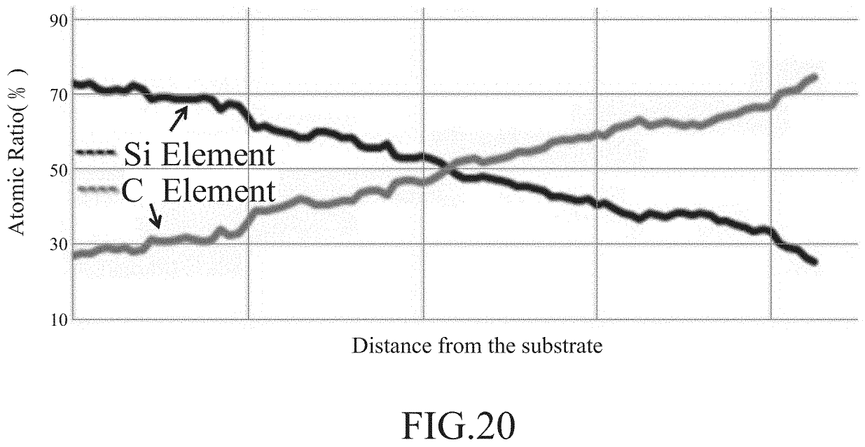

FIG. 20 is a chart showing the result of EDS analysis taken along line (L2) of FIG. 19. As shown in FIGS. 19 and 20, the carbon content (i.e., atomic ratio of carbon) in the protective coating 418 increases along the line (L2) (e.g., increases in a direction away from the substrate 402), and the silicon content (i.e., atomic ratio of silicon) in the protective coating 418 decreases in the direction away from the substrate 402. In other words, an atomic ratio of silicon is larger than that of carbon near the substrate 402. On the contrary, the atomic ratio of silicon is smaller than that of carbon near the outer surface of the protective coating 418 away from the substrate 402. More specifically, the atomic ratio of silicon is larger than 70, while that of carbon is smaller than 30% near the substrate 402 and the atomic ratio of carbon is larger than 70% while that of silicon is smaller than 30% near the outer surface of the protective coating 418. The average relative content of silicon to carbon in the protective coating 418 is near 1 (i.e., Si:C=50:50). The curve of silicon element and the curve of carbon intersect at a point around one half of the distance from the substrate 402. As a result, the carbon content as a whole would be nearly equal to the silicon content as a whole in the protective coating 418.

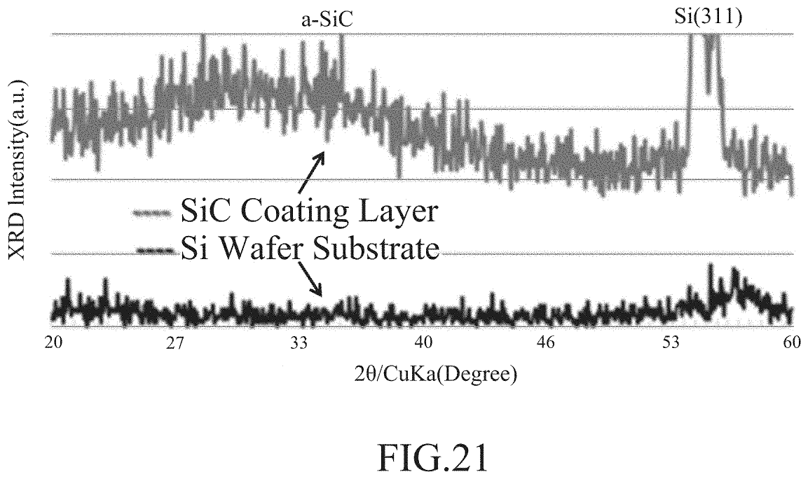

FIG. 21 is the result of XRD analysis of the surface of the protective coating 418 shown in FIG. 19. The protective coating 418 at least contains 3C—SiC such as amorphous silicon carbide (a-SiC).

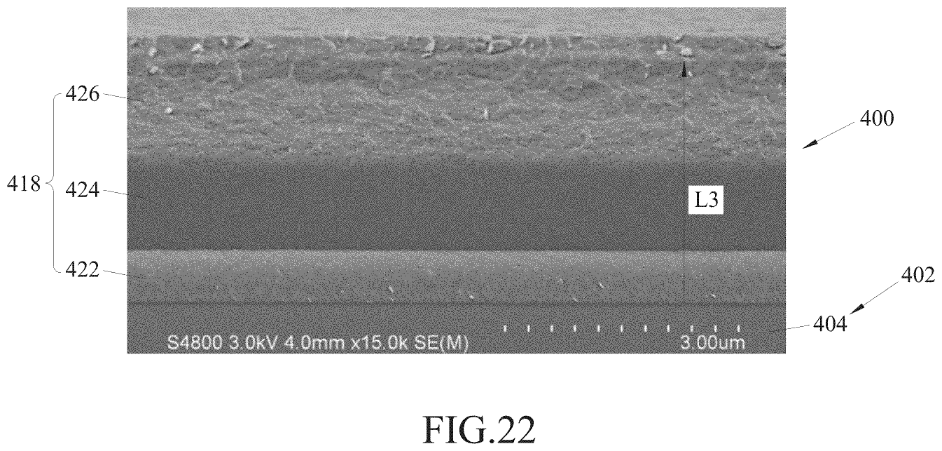

FIG. 22 is an SEM image of yet another example of the part 400. In the process for making this example, the inert gas is Ar with a flow rate ranging from 5 slm to 18 slm, but other ranges are also possible based on practical requirements. The reactive gas is C₂H₂ with a flow rate ranging from 10 sccm to 120 sccm, but other ranges are also possible based on practical requirements. The pressure within the chamber 302 ranges from 10⁻¹ torr to 10⁻² torr, but other ranges are also possible based on practical requirements. The radiofrequency power for ionizing the inert gas initially ranges from 0.4 kW to 0.7 kW, but other ranges are also possible based on practical requirements. Then, the radiofrequency power is increased to a range of 0.7 kW to 0.9 kW, but other ranges are also possible based on practical requirements. Afterwards, the radiofrequency power is further increased to a range of 0.9 kW to 1.2 kW, but other ranges are also possible based on practical requirements. The temperature of the deposition process may be below 250° C., but other ranges are also possible based on practical requirements. For example, a deposition temperature of 1200° C. can increase the ratio of crystalline silicon carbide which enhances the etch resistance capability. In other words, in some embodiments of the method for making the part 400, at least one of the flow rate of the inert gas, the flow rate of the reactive gas, and the radiofrequency power for ionizing the inert gas dynamically changes and ends up with a larger numerical value compared to an initial numerical value (i.e., the abovementioned values may be dynamically increased) during the process of formation of the protective coating 418.

As shown in FIG. 22, the protective coating 418 of the part 400 was formed to have the first portion 422, the second portion 424 and a third portion 426. The first portion 422 is connected to the substrate 402 and the second portion 424, and the third portion 426 is connected to the second portion 424 and is opposite to the first portion 422. The third portion 426 has a larger atomic ratio of carbon near outer surface of the protective coating 418 than that of the first portion 422 near the substrate 402.

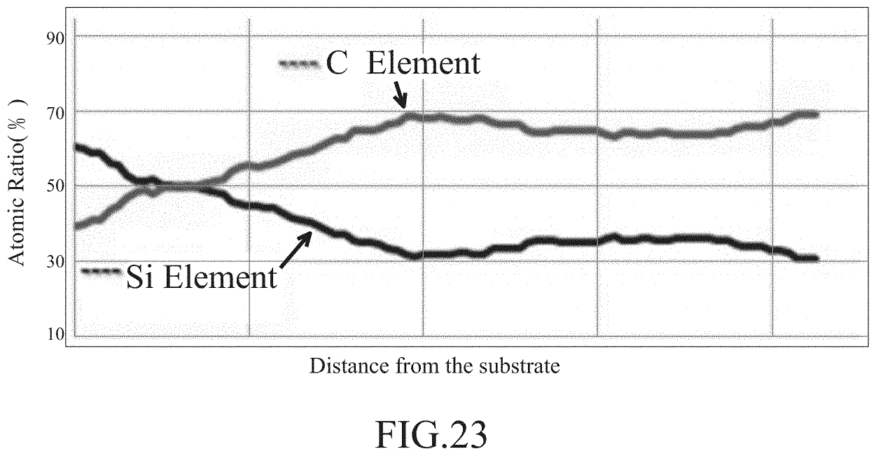

FIG. 23 is a chart showing the result of EDS analysis taken along line (L3) of FIG. 20. As shown in FIGS. 20 and 21, the carbon content (i.e., the atomic ratio of carbon) in the protective coating 418 increases along the line (L3) (e.g., increases in a direction away from the substrate 402), and the silicon content (i.e., the atomic ratio of silicon) in the protective coating 418 decreases in the direction away from the substrate 402. In other words, an atomic ratio of silicon is larger than that of carbon near the substrate 402. On the contrary, the atomic ratio of silicon is smaller than that of carbon near the outer surface of the protective coating 418 away from the substrate 402. More specifically, the atomic ratio of silicon is larger than 55% while that of carbon is smaller than 45% near the substrate 402 and the atomic ratio of carbon is about 70% while that of silicon is about 30% near the outer surface of the protective coating 418. The average relative content of silicon to carbon in the protective coating 418 is near two-thirds (i.e., Si:C=40:60). The curve of silicon element and the curve of carbon intersect at a point less than one half of the distance from the substrate 402. As a result, the carbon content as a whole would be larger than the silicon content as a whole in the protective coating 418.

In some embodiments, the relative content of silicon to carbon in the protective coating 418 (i.e., silicon carbide) ranges from two-thirds to one-and-a-half, but other ranges are also possible based on practical requirements.

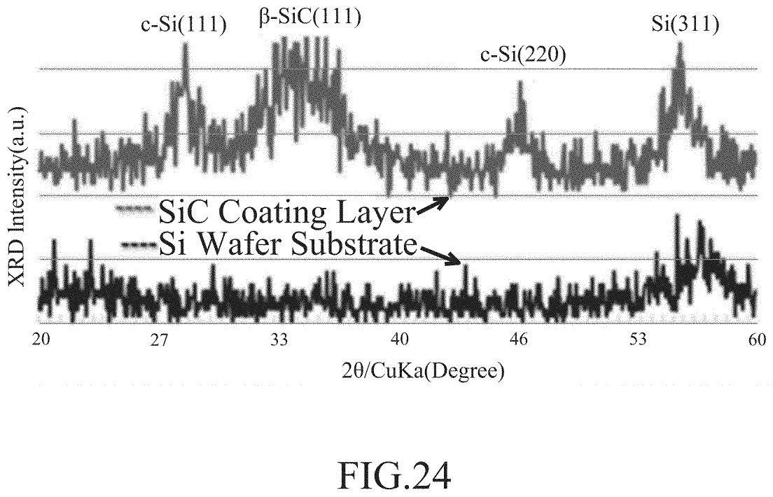

FIG. 24 is the result of XRD analysis of the surface of the protective coating 418 shown in FIG. 22. The protective coating 418 at least contains c-Si(111), c-Si(220), 3C—SiC such as β-SiC(111) (i.e., crystalline cubic SiC).

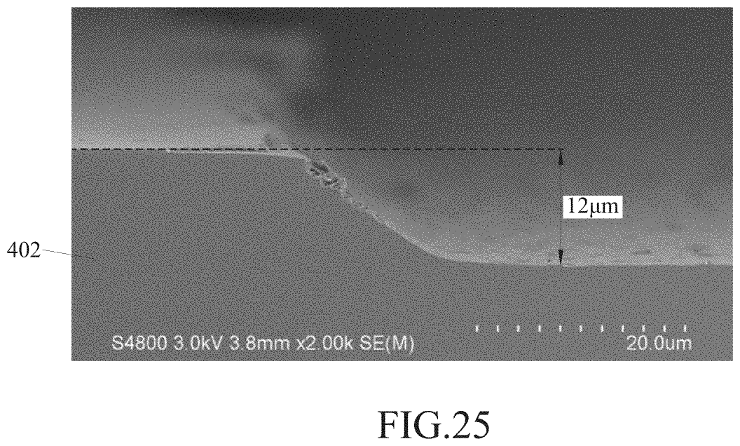

FIGS. 25 to 28 show various examples according to this disclosure that are etched in a dry etching equipment (Tokyo Electron Model 4502) at a reactive ion etching (RIE) mode, in which gaseous SiF₆ and Cl₂ were used as etchant gas, the RF power was 1000 W, and the etch time was 200 sec.

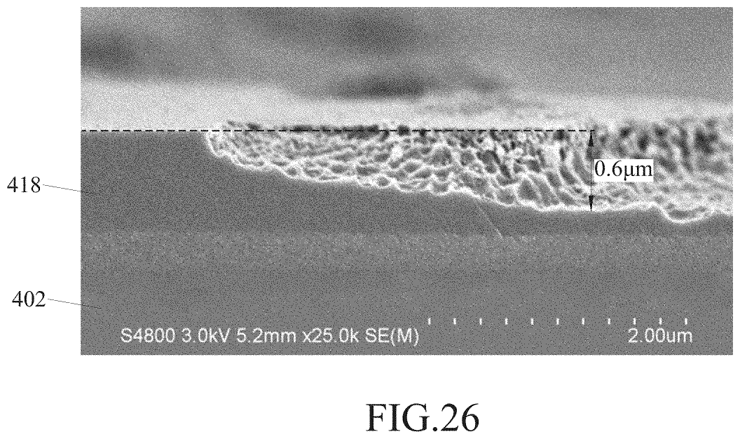

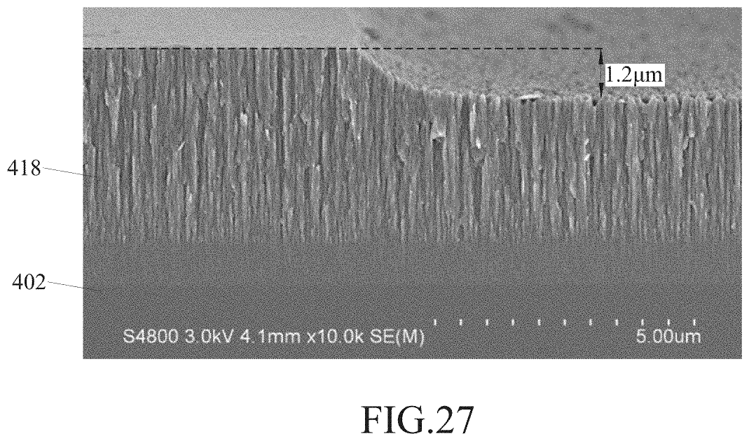

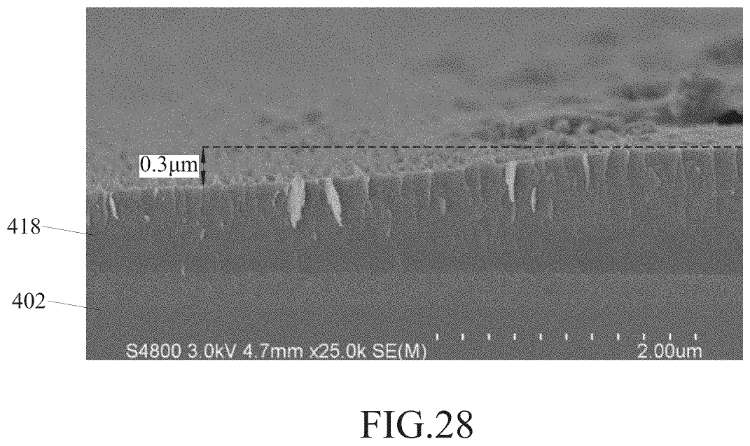

FIG. 25 shows a Si(100) wafer substrate with the same material as substrate 402 being etched at the RIE mode of the dry etching equipment under the aforementioned conditions, in which the etch rate of the wafer substrate was calculated to be 216 μm/hr. FIG. 26 shows the part 400 shown in FIG. 16 that was etched at the RIE mode under the aforementioned conditions, in which the etch rate of the protective coating 418 was calculated to be 10.8 μm/hr. FIG. 27 shows the part 400 shown in FIG. 19 that was etched at the RIE mode under the aforementioned conditions, in which the etch rate of the protective coating 418 was calculated to be 21.6 μm/hr. FIG. 28 shows the part 400 shown in FIG. 22 that was etched at the RIE mode under the aforementioned conditions, in which the etch rate of the protective coating 418 was calculated to be 5.4 μm/hr. Therefore, by having the protective coating 418, the etch rate of the part 400 is reduced. In some embodiments, a relative etch rate of the protective coating 418 to the Si(100) substrate 402 is not greater than one tenth. Compared to amorphous silicon carbide, the higher the ratio of crystalline silicon carbide (e.g., β-SiC(111)) is, the higher the etch resistance capability can be achieved. In some embodiments (not shown), a relative etch rate of the protective coating 418 to the Si(100) substrate 402 may be not greater than three-fifths (i.e., ⅗) due to various etchant gases, RF powers, or etch times, scale of the part 400.

In the aforementioned embodiments, the protective coating 418 may have a crystalline ratio ranging from 0% to 17%. But in other embodiments with higher process temperature or an annealing temperature up to 800° C., the crystalline ratio may be up to 60%. That is, other ranges are also possible based on practical requirements. The crystalline ratio of the protective coating 418 in accordance with some embodiments of this disclosure may range from 0% to 5%, from 5, to 10%, from 10% to 15%, from 15% to 17%, from 17% to 20%, from 20% to 25%, from 25 to 30%, from 35% to 40%, from 40% to 45%, from 45 to 50%, from 50% to 55%, from 55% to 60%, or other ranges of values, such as 80% when the process temperature or an annealing temperature up to 1200° C.

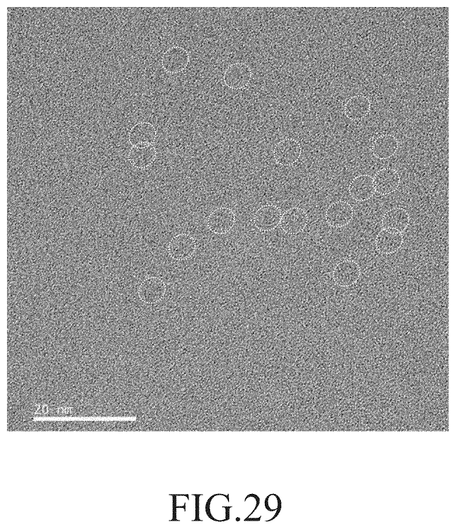

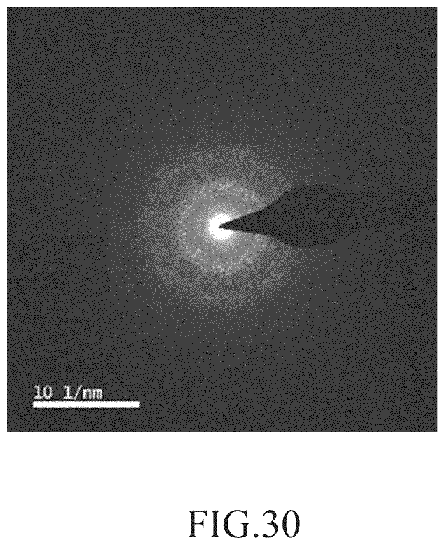

FIG. 29 is a High Resolution Transmission Electron Microscope (HRTEM) image of the sample in FIG. 16 taken by JEOL Model JEM-2100F. Moreover, FIG. 30 shows the corresponding diffraction pattern of the example as shown in FIG. 16. The detected position shown in FIGS. 29 and 30 is 1 μm deep from the outer surface of protective coating 418 as shown in FIG. 16. The circles formed by white dots represent the area of crystalline and the crystalline ratio was calculated to be 5% from the result of FIG. 29.

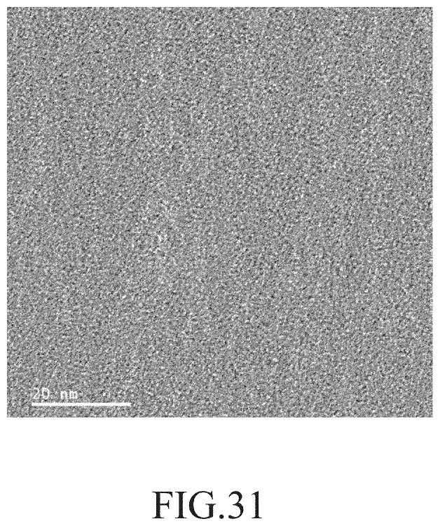

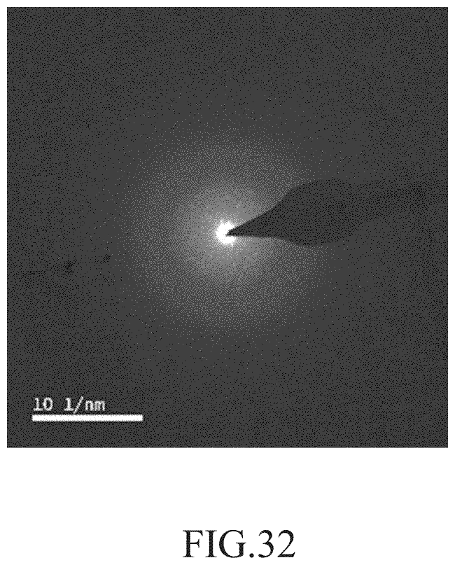

FIG. 31 is an HRTEM image of the sample in FIG. 19 taken by JEOL Model JEM-2100F. Moreover, FIG. 32 shows the corresponding diffraction pattern of the example as shown in FIG. 19. The detected position shown in FIGS. 31 and 32 is 1 μm deep from the outer surface of protective coating 418 as shown in FIG. 19. The crystalline ratio was calculated to be 0% from the result of FIG. 31, which represents the existence of amorphous SiC.

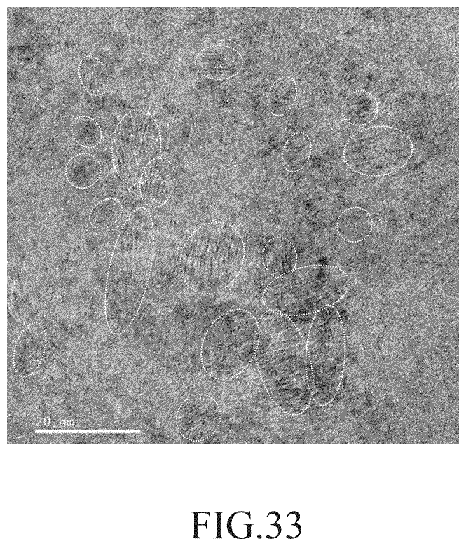

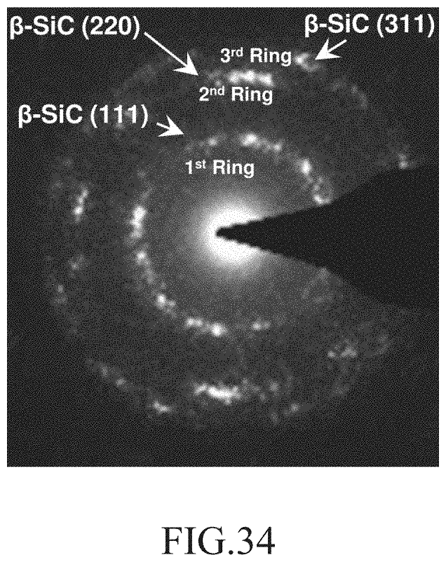

FIG. 33 is an HRTEM image of the sample in FIG. 22 taken by JEOL Model JEM-2100F. Moreover, FIG. 34 shows the corresponding diffraction pattern of the example as shown in FIG. 22. The detected position shown in FIGS. 33 and 34 is 1 μm deep from the outer surface of protective coating 418 as shown in FIG. 22. The circles formed by white dots represent the area of crystalline and the crystalline ratio was calculated to be 17% from the result of FIG. 33. As shown in FIG. 34, there are three rings in the diffraction pattern in FIG. 34. The first ring near the center represents β-SiC(111). The second ring near the first ring represents β-SiC(220). The third ring outermost represents β-SiC(311). That is, except β-SiC(111), the area of crystalline structure further includes β-SiC(220) and β-SiC (311). Compared to XRD, HRTEM can measure nano scale area and the diffraction pattern is more specific to realize the compound of crystalline structures.

Since the silicon surface atomic density of silicon (111) and (100) surfaces are 7.83×10¹⁴/cm² and 6.78×10¹⁴/cm², respectively, more silicon fluoride bonds or silicon chloride bonds of etching byproducts are needed to be formed on the silicon(111) surface compared to those on the silicon(100) surface. Therefore, the etch rate of silicon (111) can be lower than that of silicon (100). In other words, the aforementioned embodiments having c-Si (111) also can decrease the etch rate of various etchant gases, such as gaseous CF₄, SiF₆, Cl₂, etc.

Moreover, the etch resistance capability may be higher when the relative content ratio of carbon to silicon as a whole in the protective coating 418 (i.e., silicon carbide) is larger than 1, such as 1.5, but other ranges larger than one, for example, 1.1, 1.3 or 1.8, are also possible based on practical requirements.

In addition, the resistance of the protective coating 418 in the aforementioned embodiments can be adjusted to a target value such as the same value as that of substrate 402 or other values by doping nitrogen element.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

1. A part adapted to be used in a semiconductor processing equipment, the part comprising:
a substrate made of silicon; and
a protective coating that covers at least a part of the substrate,
wherein an atomic ratio of carbon in the protective coating increases in a direction away from the substrate, and an atomic ratio of silicon in the protective coating decreases in the direction, and
wherein the atomic ratio of silicon in the protective coating is larger than that of carbon near the substrate, and the atomic ratio of silicon in the protective coating is smaller than that of carbon near an outer surface of the protective coating.

2. The part as claimed in claim 1, wherein the atomic ratio of silicon is larger than 50% near the substrate and the atomic ratio of carbon is larger than 50% near the outer surface of the protective coating.

3. The part as claimed in claim 1, wherein the protective coating includes crystalline silicon having (111) facets, (220) facets, or a combination thereof.

4. The part as claimed in claim 1, wherein:
the protective coating includes 3C—SiC formed by reactive physical vapor deposition; and
the 3C—SiC includes amorphous silicon carbide or crystalline silicon carbide having (111) facets.

5. The part as claimed in claim 1, wherein a relative content of silicon to carbon of the protective coating ranges from two-thirds to one-and-a-half.

6. The part as claimed in claim 1, wherein the protective coating has a first portion and a second portion, the first portion being connected to the substrate and the second portion and having a larger atomic ratio of silicon near the substrate than that of the second portion.

7. The part as claimed in claim 6, wherein the protective coating has a third portion connected to the second portion and opposite to the first portion, the third portion having a larger atomic ratio of carbon than that of the first portion near the substrate.

8. The part as claimed in claim 1, wherein the protective coating has a crystalline ratio ranging from 0% to 60%.

9. The part as claimed in claim 1, wherein a relative etch rate of the protective coating to the substrate is not greater than three-fifths when a reactive gas includes gaseous SF6 and Cl2 in a dry etcher at reactive ion etching (RIE) mode.

10. The part as claimed in claim 1, wherein the substrate has a surface including a plurality of microstructures each having a height in a range from 300 nm to 1.5 μm, and the protective coating has a minimum thickness of not less than 10 μm.

11. The part as claimed in claim 1, wherein the protective coating has a minimum thickness of not less than 1.5 μm.

12. The part as claimed in claim 1, wherein the part is a closed-loop object.

13. The part as claimed in claim 12 wherein the closed-loop object is a focus ring used in a dry etching equipment.

14. A method for making a part adapted to be used in a semiconductor processing equipment, the method comprising:
introducing an inert gas into a chamber which contains a plurality of silicon targets and a substrate made of silicon;
introducing a reactive gas which includes an element of carbon into the chamber; and
ionizing the inert gas into plasma such that the plasma hits the silicon targets, causing silicon atoms to break away from the silicon targets and to react with the reactive gas so as to form a protective coating of silicon carbide that covers at least a part of the substrate.

15. The method as claimed in claim 14, further comprising, before introducing the inert gas and the reactive gas, placing an even number of the silicon targets in the chamber, the silicon targets being arranged in at least one pair with the silicon targets facing each other.

16. The method as claimed in claim 15, further comprising rotating the substrate which is a closed-loop object about a virtual center axis.

17. The method as claimed in claim 14, further comprising:
biasing the substrate such that at least a part of ions of the plasma hits the substrate to remove oxidized layers on the substrate and to create dangling bonds at the surface of the substrate,
wherein the protective coating is formed on the substrate through chemical bonding with the dangling bonds.

18. The method as claimed in claim 14, further comprising heating or annealing the substrate to a temperature lower than the melting points of silicon carbide and the substrate.

19. The method as claimed in claim 14, wherein at least one of a flow rate of the inert gas, a flow rate of the reactive gas and a radiofrequency power for ionizing the inert gas dynamically changes and ends up with a larger numerical value compared to an initial numerical value during the process of formation of the protective coating.

20. The method as claimed in claim 19, wherein:
the flow rate of the inert gas ranges from 5 slm to 24 slm;
the flow rate of the reactive gas ranges from 10 sccm to 120 sccm; and
the radiofrequency power ranges from 0.4 kW to 1.2 kW.

21. The method as claimed in claim 14, wherein a rate of forming the protective coating is not less than 6 Å/sec.
